(19) United States
(12) Patent Application Publication
(10) Pub. No.: US 2021/0041904 A1
(43) Pub. Date: Feb. 11, 2021

(54) CURRENT SOURCE CIRCUIT

(71) Applicant: SITRONIX TECHNOLOGY CORP., JHUBEI CITY (TW)

(72) Inventors: CHIH-TE HUNG, JHUBEI CITY (TW); I-CHEN LIN, JHUBEI CITY (TW)

(21) Appl. No.: 16/826,652

(22) Filed: Mar. 23, 2020

Related U.S. Application Data
(60) Provisional application No. 62/822,160, filed on Mar. 22, 2019.

(51) Int. Cl. G05F 3/26; H03K 17/56; G05F 1/46

(52) U.S. Cl. CPC G05F 3/262; G05F 1/46; H03K 17/56

(57) ABSTRACT

The invention relates to a current source circuit, which includes a current generating circuit, a plurality of current mirror circuits, and a switching circuit. The current generating circuit generates a plurality of reference currents, which comprise a first reference current and a second reference current. The current mirror circuits output a plurality of mirror currents according to the first reference current and the second reference current. The switching circuit is coupled between the current generating circuit and the current mirror circuits. The first reference current is transmitted to the current mirror circuits through the switching circuit, and the second reference current is transmitted to the current mirror circuits through the switching circuit.

### FIELD OF THE INVENTION

The present invention relates generally to a current source circuit, and particularly to a current source circuit with dynamic element matching.

### BACKGROUND OF THE INVENTION

Please refer to FIG. 1, which shows a circuit diagram of the conventional current generating circuit. As shown in the figure, the current generating circuit is coupled to a power voltage VDD and a ground voltage GND and generates a plurality of currents Ia, Ib, Ic, Id, Ie. The current generating circuit includes a plurality of transistors M1, M2, M3, M4, M5, M6, M7. The transistor M1 is coupled between a current source CS and the ground voltage GND and a current Ics flows through. The current source CS generates the current Ics according to the power voltage VDD. In addition, the gate of the transistor M1 is coupled to the drain; the source of the transistor M1 is coupled to the ground voltage GND. The gate of the transistor M2 is coupled to the gate and drain of the transistor M1; and the gate of the transistor M2 is coupled to the current source CS. Thereby, the current Ics controls the transistors M1, M2 to turn on. Besides, after the transistor M2 is turned on, the transistor M3 will be turned on and generating the current Ia. In other words, the transistor M2 controls the level of the current Ia. Moreover, the gates of the transistors M1, M2 are controlled by the current Ics; the size of the transistor M1 may be in proportion to the size of the transistor M2. Accordingly, the current Ics controls that the current flowing through the transistor M1 is in proportion to the current flowing through the transistor M2. For example, the current Ia is once or twice the current Ics.

Likewise, the current la controls the transistors M4, M5, M6, M7 to generate the currents Ib, Ic, Id, Ie, respectively. In addition, the currents Ib, Ic, Id, Ie is in proportion to the current Ia. For example, the currents Ib, Ic, Id, Ie are 2 μA and the current Ia is 1 μA. Nonetheless, the power voltage VDD is supplied to multiple transistors M4˜M7 via wires. When the wires becomes longer, the influence of wire resistance R1, R2, R3, R4 on the power voltage VDD becomes greater. That is to say, the voltage drop across the wires will be more significant. For example, the transistor M4 is coupled to the full power voltage VDD. As for the transistor M7, owing to the wire resistance, the coupled voltage level will be a half of the power voltage VDD. Consequently, the levels of the currents Ib, Ic, Id, Ie will mismatch. Likewise, the ground wire responsible for conducting the ground voltage GND will also lead to mismatch between the current Ia and the current Ics.

According to the problem of the conventional current generating circuit, the present invention provides a current source circuit with dynamic element matching capable of reducing mismatch in output currents caused by voltage drops in power and ground wires.

### SUMMARY

An objective of the present invention is to provide a current source circuit, which may reduce mismatch in output currents caused by voltage drops in power and ground wires.

The present invention relates to a current source circuit, which comprises a current generating circuit, a plurality of current mirror circuits, and a switching circuit. The current generating circuit generates a plurality of reference currents, which include a first reference current and a second reference current. The current mirror circuits output a plurality of mirror currents according to the first reference current and the second reference current. The switching circuit is coupled between the current generating circuit and the current mirror circuits. The first reference current flows to the current mirror circuits via the switching circuit; and the second reference current flows to the current mirror circuits via the switching circuit.

### BRIEF DESCRIPTION OF THE DRAWINGS

FIG. 1 shows a circuit diagram of the conventional current generating circuit;

FIG. 2 shows a circuit diagram of the current source circuit according to the first embodiment of the present invention;

FIG. 3 shows a circuit diagram of the current source circuit according to the second embodiment of the present invention;

FIG. 4A shows a circuit diagram of the switching circuit shown in FIG. 2 according to the present invention;

FIG. 4B shows a circuit diagram of the switching circuit shown in FIG. 3 according to the present invention;

FIG. 5 shows a circuit diagram of the current source circuit according to the third embodiment of the present invention;

FIG. 6 shows a circuit diagram of the current source circuit according to the fourth embodiment of the present invention;

FIG. 7A shows a circuit diagram of the switching circuit shown in FIG. 5 according to the present invention;

FIG. 7B shows a circuit diagram of the switching circuit shown in FIG. 6 according to the present invention; and

FIG. 8 shows a circuit diagram of the current source circuit according to the fifth embodiment of the present invention.

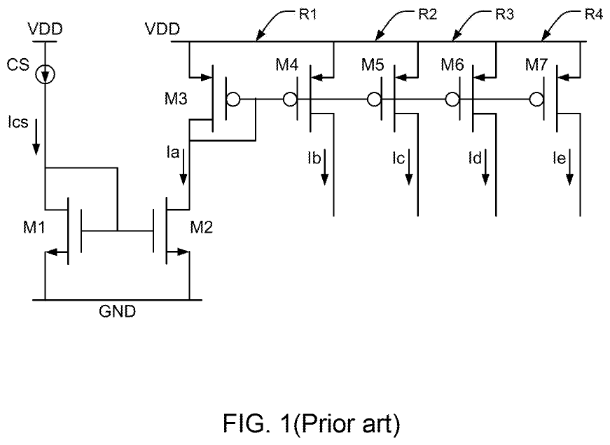

### DETAILED DESCRIPTION

In the specifications and claims, certain words are used for representing specific devices. A person having ordinary skill in the art should know that hardware manufacturers might use different nouns to call the same device. In the specifications and claims, the differences in names are not used for distinguishing devices. Instead, the differences in technique as in whole are the guidelines for distinguishing. In the whole specifications and claims, the word “comprising” is an open language and should be explained as “comprising but not limited to”. Besides, the word “couple” includes any direct and indirect connection. Thereby, if the description is that a first device is coupled to a second device, it means that the first device is connected to the second device directly, or the first device is connected to the second device via other device or connecting means indirectly.

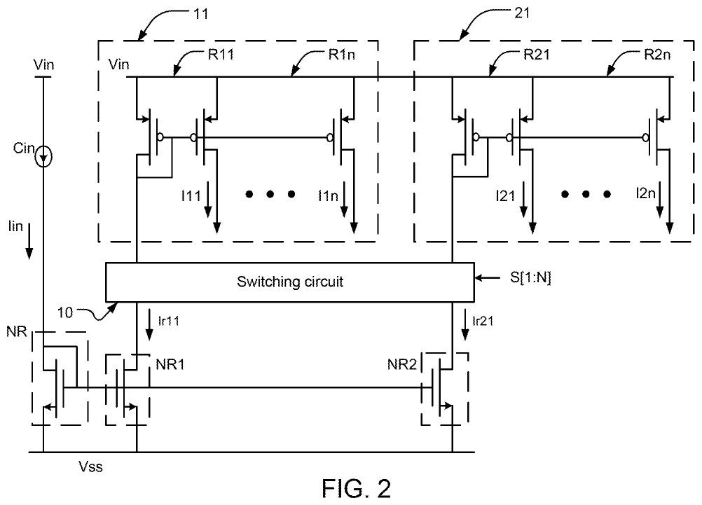

Please refer to FIG. 2, which shows a circuit diagram of the current source circuit according to the first embodiment of the present invention. As shown in the figure, a current generating circuit generates a first reference current Ir11 and a second reference current Ir21. A plurality of current mirror circuits 11, 21 outputs a plurality of mirror currents I11˜I1n, I21˜I2n according to the first reference current Ir11 and the second reference current Ir21. A switching circuit 10 is coupled between the current generating circuit and the current mirror circuits 11, 21. Thereby, the first reference current Ir11 may flow to the current mirror circuit 11, 21 through the switching circuit 10, and the second reference current Ir21 may flow to the current mirror circuit 11, 21 through the switching circuit 10. The mirror currents include at least one first mirror current I11 and at least one second mirror current I21. The mirror currents according to the embodiment in FIG. 2 include a plurality of first mirror currents I11˜I1n and a plurality of second mirror currents I21˜I2n. The current generating circuit of the current source circuit includes a first reference current source NR1 and a second reference current source NR2. A plurality of current mirror circuits of the current source circuit include a first current mirror circuit 11 and a second current mirror circuit 21. Besides, the current source circuit further comprises a switching circuit 10, which may be a dynamic element matching (DEM) circuit. The first current mirror circuit 11 is coupled to the first reference current source NR1 or the second reference current source NR2; the second current mirror circuit 21 is coupled to the second reference current source NR2 or the first reference current source NR1. The switching circuit 10 receives a plurality of switching signals S[1:N] and is coupled to the first reference current source NR1, the second reference current source NR2, the first current mirror circuit 11, and the second current mirror circuit 21. In addition, the current generating circuit further includes an input circuit NR, which is coupled to a current source Cin. The current source Cin is coupled to an input voltage Vin. Thereby, the current source Cin generates an input current Iin according to the input voltage Vin. According to an embodiment of the present invention, the current source Cin may generate the input current Iin according to a voltage different from the input voltage Vin. The input current Iin is coupled to the input circuit NR and is coupled to the first reference current source NR1 and the second reference current source NR2 through the input circuit NR. Thereby, the first reference current source NR and the second reference current source NR2 generate the first reference current Ir11 and the second reference current Ir21 according to the input current Iin. In other words, the first reference current source NR1 generates the first reference current Ir11 according to the input current Iin; and the second reference current source NR2 generates the second reference current Ir21 according to the input current Iin.

Moreover, the switching circuit 10 controls the current mirror circuits 11, 12 to couple to the first reference current source NR1 and the second reference current source NR2. In other words, the switching circuit 10 controls the current mirror circuits 11, 12 to dynamically element match the first reference current source NR1 or the second reference current source NR2. To control dynamic element matching, for example, the switching circuit 10 controls the time for which the first current mirror circuit 11 and the second current mirror circuit 21 are coupled to the first reference current source NR1 and the second reference current source NR2, respectively, to be 50% of the time for a display panel displaying a frame (50% matching time). In addition, by means of the switching control of the switching circuit 10, the first current mirror circuit 11 and the second current mirror circuit 21 are changed to couple to the second reference current source NR2 and the first current source NR1, respectively, for the remaining 50% of a frame time. Thereby, the first current mirror circuit 11 generates the first mirror currents I11˜I1n according to the first reference current Ir11 and the second reference current Ir21, respectively; the second current mirror circuit 21 generates the second mirror currents I21˜I2n according to the second reference current Ir21 and the first reference current Ir11, respectively. Besides, the display panel may be a passive matrix organic light-emitting diode (PMOLED).

Please refer again to FIG. 2. Under the control of the switching circuit 10 according to the switching signals S[1:N], the first current mirror circuit 11 generates the first mirror currents I11˜I1n according to the first reference current Ir11; the second current mirror circuit 21 generates the second mirror currents I21˜I2n according to the second reference current Ir21. Alternatively, the first current mirror circuit 11 generates the first mirror currents I11˜I1n according to the second reference current Ir21; the second current mirror circuit 21 generates the second mirror currents I21˜I2n according to the first reference current Ir11. In addition, originally, the first reference current source NR1 and the second reference current source NR2 are designed to generate the first reference current Ir11 and the second reference current Ir21 with identical levels. Nonetheless, due to the element variation in the fabrication process, the first reference current source NR1 and the second reference current source NR2 might generate the first reference current Ir11 and the second reference current Ir21 with different levels. For example, the first reference current Ir11 and the second reference current Ir21 are both designed to be 10 μA. However, owing to process variations, the second reference current Ir21 becomes 8 μA. Accordingly, the mirror currents I11˜I1n, I21˜I2n generated by the current source circuit might mismatch.

Nonetheless, the switching circuit 10 may control dynamic element matching. When the switching circuit 10 switches the first current mirror circuit 11 to couple to the first reference current source NR1, the first current mirror circuit 11 generates the first mirror currents I11˜I1n according to the 10 μA first reference current Ir11. Assuming that the first current mirror circuit 11 generates once the mirror current, the first mirror currents I11˜I1n will be 10 μA as well. When the switching circuit 10 switches the first current mirror circuit 11 to couple to the second reference current source NR2, the first current mirror circuit 11 generates the first mirror currents I11˜I1n according to the 8 μA second reference current Ir21. Likewise, assuming that the first current mirror circuit 11 generates once the mirror current, the first mirror currents I11˜I1n will be 8 μA as well. Thereby, under dynamic element matching, the average reference current supplied to the first current mirror circuit 11 by the first reference current source NR1 and the second reference current source NR2 is 9 μA. Hence, the average first mirror currents I11˜I1n generated by the first current mirror circuit 11 is 9 μA.

When the switching circuit 10 switches the second current mirror circuit 21 to couple to the second reference current source NR2, the second current mirror circuit 21 generates the second mirror currents I21˜I2n according to the 8 μA second reference current Ir21. Assuming that the second current mirror circuit 21 generates once the mirror current, the second mirror currents I21˜I2n will be 8 μA as well. When the switching circuit 10 switches the second current mirror circuit 21 to couple to the first reference current source NR1, the second current mirror circuit 21 generates the second mirror currents I21˜I2n according to the 10 μA first reference current Ir11. Assuming that the second current mirror circuit 21 generates once the mirror current, the second mirror currents I21˜I2n will be 10 μA as well. Thereby, the average reference current supplied to the second current mirror circuit 21 by the first reference current source NR1 and the second reference current source NR2 is 9 μA. Hence, the average second mirror current I21˜I2n generated by the second current mirror circuit 21 is 9 μA. In other words, the mirror currents I11˜I1n, I21˜I2n generated by the first and second current mirror circuits 11, 21 are changed from a mismatched condition to a matched one. For example, the average of the first mirror currents I11˜I1n and the average of the second mirror currents I21˜I2n are both 9 μA.

Accordingly, when the currents generated by the first reference current source NR1 and the second reference current source NR2 are mismatched due to process variations in elements, the switching circuit 10 may switch to control the matching between the first reference current source NR1 and the second reference current source NR2 for generating the matched first and second mirror currents I11˜I1n, I21˜I2n. Thereby, under the control of dynamic circuit matching by the switching circuit 10, the first and second mirror currents I11-I1n, I21˜I2n of the first and second current mirror circuits 11, 21 (of among the element groups) are matched. The multiple of mirror current, the current value, the number of reference currents, and the number of mirror currents described above are used for illustrating the embodiment instead of limiting the present invention.

In addition, the first current mirror circuit 11 and the second current mirror circuit 21 are coupled to the first reference current Ir11 or the second reference current Ir21 respectively to generate the mirror currents I11˜I1n, I21˜I2n. Thereby, the problem of mismatch in output currents due to voltage drop for long wires in the current source circuit adopting a single current mirror circuit to generate multiple currents according to the prior art may be solved.

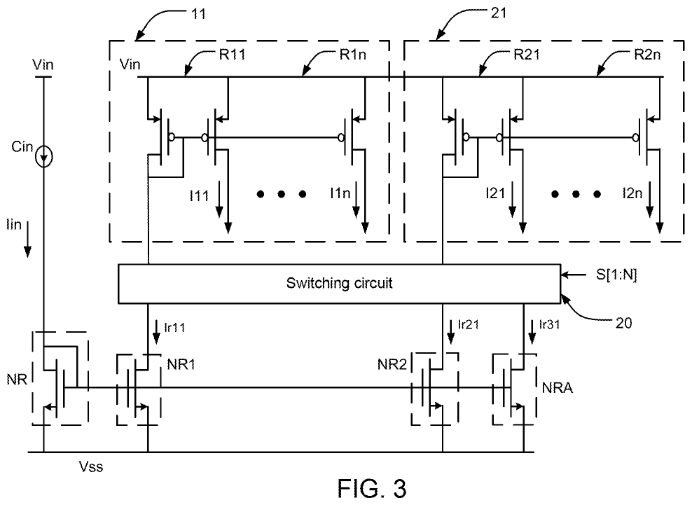

Please refer to FIG. 3, which shows a circuit diagram of the current source circuit according to the second embodiment of the present invention. As shown in the figure, the input circuits NR according to the embodiments in FIG. 3 and FIG. 2 are coupled between the current source Cin and the reference level Vss. The first current mirror circuit 11 is in parallel with the second current mirror circuit 21. In addition, the first reference current source NR1 and the second reference current source NR2 are coupled between the switching circuit 10 and the reference level Vss. The difference between the embodiments in FIG. 3 and in FIG. 2 is that the current generating circuit according to the embodiment in FIG. 3 further includes a third reference current source NRA coupled to the switching circuit 20. By means of the switching of the switching circuit 20, the third reference current source NRA may be coupled to the first current mirror circuit 11 or the second current mirror circuit 21. Besides, the third reference current source NRA generates a third reference current Ir31 according to the input current Iin. When the switching circuit 20 switches the first current mirror circuit 11 to couple to the third reference current source NRA, the switching circuit 20 cuts off the coupling between the first current mirror circuit 11 to the first reference current source NR1 and the second reference current source NR2. When the switching circuit 20 switches the second current mirror circuit 21 to couple to the third reference current source NRA, the switching circuit 20 cuts off the coupling between the second current mirror circuit 21 to the first reference current source NR1 and the second reference current source NR2. Thereby, the first current mirror circuit 11 generates the first mirror currents I11˜I1n according to the third reference current Ir31. Alternatively, the second current mirror circuit 21 generates the second mirror currents I21˜I2n according to the third reference current Ir31.

Please refer again to FIG. 3. When a plurality of elements generating the mirror currents are divided into two element groups, for example, the first current mirror circuit 11 and the second current mirror circuit 21, the number of the reference current sources NR1, NR2, NRA may be greater than the number of element groups. In other words, the number of the reference currents Ir11, Ir21, Ir31 may be greater than the number of the current mirror circuits 11, 12. For example, according to the embodiment in FIG. 3, three reference current sources NR1, NR2, NRA generate three reference currents Ir11, Ir21, Ir31. The number of the reference currents Ir11, Ir21, Ir31 is greater than the number of the current mirror circuits 11, 12. That is to say, according to the embodiment in FIG. 3, the third reference current source NRA is added for dynamic element matching. Therefore, dynamic element matching is not limited to using the first reference current source NR1 and the second reference current source NR2. Namely, the current mirror circuits 11, 21 generate the mirror currents I11˜I1n, I21˜I2n according to at least two of the first to third reference currents Ir11, Ir21, Ir31. According to the embodiment in FIG. 3, the method for generating the average mirror current and the average reference current is identical to the description according to the embodiment in FIG. 2. Hence, the details will not be described again.

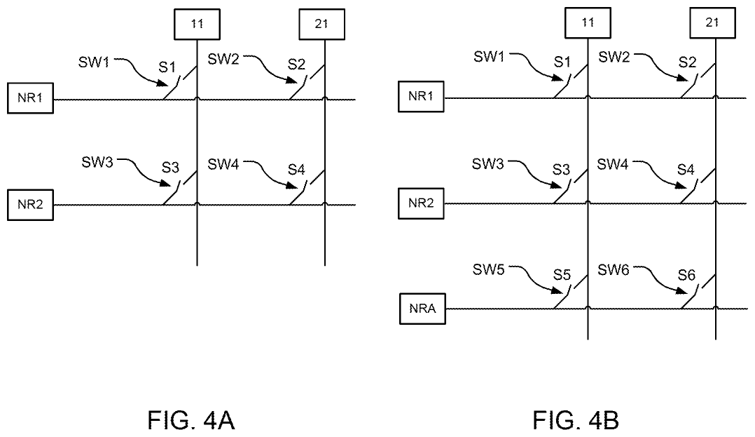

Please refer to FIG. 4A, which shows a circuit diagram of the switching circuit in FIG. 2 according to the present invention. As shown in the figure, the switching circuit 10 according to the embodiment in FIG. 2 includes a first switch SW1, a second switch SW2, a third switch SW3, and a fourth switch SW4. The first switch SW1 is coupled between the first current mirror circuit 11 and the first reference current source NR1. The second switch SW2 is coupled between the second current mirror circuit 21 and the first reference current source NR1. The third switch SW3 is coupled between the first current mirror circuit 11 and the second reference current source NR2. The fourth switch SW4 is coupled between the second current mirror circuit 21 and the second reference current source NR2. In other words, the first switch SW1 is coupled between the first current mirror circuit 11 and the first reference current Ir11. The second switch SW2 is coupled between the second current mirror circuit 21 and the first reference current Ir11. The third switch SW3 is coupled between the first current mirror circuit 11 and the second reference current Ir21. The fourth switch SW4 is coupled between the second current mirror circuit 21 and the second reference current Ir21.

Thereby, in a period, when a first switching signal S1 controls the first switch SW1 to close (turn on), a second switching signal S2 controls the second switch SW2 to open (turn off), and when a third switching signal S3 controls the third switch SW3 to open, a fourth switching signal S4 controls the fourth switch SW4 to close. Alternatively, in a period, when a first switching signal S1 controls the first switch SW1 to open, a second switching signal S2 controls the second switch SW2 to close; and when a third switching signal S3 controls the third switch SW3 to close, a fourth switching signal S4 controls the fourth switch SW4 to open. Thereby, in a period, the first reference current Ir11 flows to the first current mirror circuit 11 via the first switch SW1 and the second reference current Ir21 flows to the second current mirror circuit 21 via the fourth switch SW4. Alternatively, in a period, the first reference current Ir11 flows to the second current mirror circuit 21 via the second switch SW2 and the second reference current Ir21 flows to the first current mirror circuit 11 via the third switch SW3.

Accordingly, the switching signals S1˜S4 control the close and open periods of the switches SW1˜SW4. In other words, the switching signals S1˜S4 control the periods of the first and second current mirror circuits 11, 21 coupling to the first and second reference current sources NR1, NR2. Thereby, the switching signals S1˜S4 may control the matching time of the current mirror circuits 11, 21 with different reference current sources NR1, NR2 and thus further controlling the average levels of the first and second mirror currents I11˜I1n, I21˜I2n. Besides, the present invention does not limit by which circuit the switching signals S1˜S4 are generated once the generated signals may control the switching of the switches SW1˜SW4 and achieving dynamic element matching.

Please refer to FIG. 4B, which shows a circuit diagram of the switching circuit in FIG. 3 according to the present invention. The embodiment in FIG. 3 further sets the third reference current source NRA. Thereby, the switching circuit according to the embodiment in figure includes the first switch SW1, the second switch SW2, the third switch SW3, the fourth switch SW4, a fifth switch SW5, and a sixth switch SW6. The first to fourth switches SW1˜SW4 have been described in the embodiment in FIG. 4A. Hence, the details will not be described again. The fifth switch SW5 is coupled between the third reference current source NRA and the first current mirror circuit 11; the sixth switch SW6 is coupled between the third reference current source NRA and the second current mirror circuit 21. In other words, the fifth switch SW5 is coupled between the third reference current Ir31 and the first current mirror circuit 11; the sixth switch SW6 is coupled between the third reference current Ir31 and the second current mirror circuit 21. Thereby, in a period, when a fifth switching signal S5 controls the fifth switch SW5 to close, the first switching signal S1 and the third switching signal S3 control the first switch SW1 and the third switch SW3 to open, and the second switching signal S2 or the fourth switching signal S4 controls the second switch SW2 or the fourth switch SW4 to close. Alternatively, in a period, when a sixth switching signal S6 controls the sixth switch SW6 to close, the second switching signal S2 and the fourth switching signal S4 control the second switch SW2 and the fourth switch SW4 to open, and the first switching signal S1 or the third switching signal S3 controls the first switch SW1 or the third switch SW3 to close.

Thereby, according to the embodiment in FIG. 4B, there are six switching combinations for dynamic element matching. In other words, the first reference current Ir11 flows to the first current mirror circuit 11 via the first switch SW1 and the second reference current Ir21 flows to the second current mirror circuit 21 via the fourth switch SW4. Alternatively, the first reference current Ir11 flows to the second current mirror circuit 21 via the second switch SW2 and the second reference current Ir21 flows to the first current mirror circuit 11 via the third switch SW3. Alternatively, the third reference current Ir31 flows to the first current mirror circuit 11 via the fifth switch SW5 and the first reference current Ir11 flows to the second current mirror circuit 21 via the second switch SW2. Alternatively, the third reference current Ir31 flows to the first current mirror circuit 11 via the fifth switch SW5 and the second reference current Ir21 flows to the second current mirror circuit 21 via the fourth switch SW4. Alternatively, the first reference current Ir11 flows to the first current mirror circuit 11 via the first switch SW1 and the third reference current Ir31 flows to the second current mirror circuit 21 via the sixth switch SW6. Alternatively, the second reference current Ir21 flows to the first current mirror circuit 11 via the third switch SW3 and the third reference current Ir31 flows to the second current mirror circuit 21 via the sixth switch SW6.

Accordingly, when the first current mirror circuit 11 generates the first mirror currents I11˜I1n according to the third reference current Ir31 generated by the third reference current source NRA, the second current mirror circuit 21 is coupled to the first reference current source NR1 or the second reference current source NR2 selectively via the second switch SW2 or the fourth switch SW4. Likewise, when the second current mirror circuit 21 generates the second mirror currents I21˜I2n according to the third reference current Ir31 generated by the third reference current source NRA, the first current mirror circuit 11 is coupled to the first reference current source NR1 or the second reference current source NR2 selectively via the first switch SW1 or the third switch SW3. In other words, the matching order for dynamic element matching is not limited in each embodiment. In addition, the dynamic element matching as described above is performed at the 50% frame time, meaning that dynamic element matching is performed once by switching the switches within a frame period. Alternatively, according to an embodiment, the switches may be switched for multiple times in a frame period for performing dynamic element matching for multiple times. Besides, in the period for multiple dynamic element matching, the first and second current mirror circuits 11, 21 may be selectively switched to different reference current sources NR1, NR2, NRA as described above. Nonetheless, for optimizing the matching effect, the current mirror circuits and reference current sources will not repeat the same matching unless they are matched once, respectively. For example, the first current mirror circuit 11 will not be matched to the three reference current sources NR1, NR2, NRA repeatedly unless it is matched to the three reference current sources NR1, NR2, NRA once, respectively.

Nonetheless, to achieve different matching effect, the method of dynamic element matching may be different from the above description. In other words, if the current mirror circuits 11, 21 and the reference current sources NR1, NR2, NRA are not required to switch once, the number of switches in the switching circuit 20 may be reduced. Thereby, the number of switching signals may be reduced correspondingly. For example, according to the embodiment in FIG. 4B, when the second current mirror circuit 21 is not required to be coupled to the third reference current source NRA, the switching circuit 20 only needs to include five switches SW1˜SW5; it is not required to receive the sixth switching signal S6.

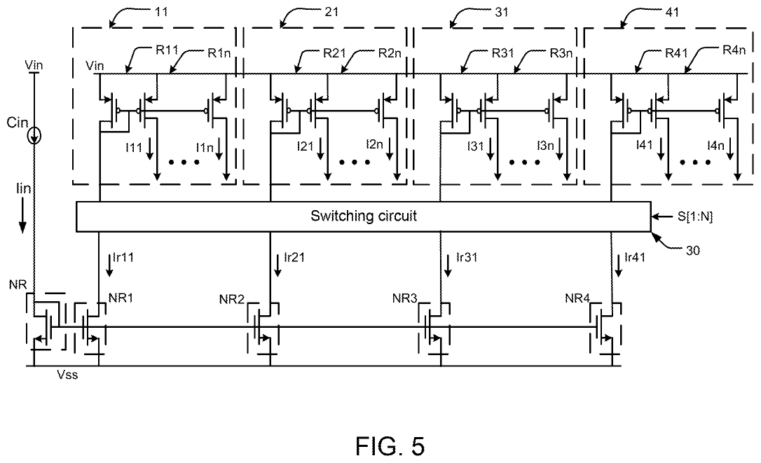

Please refer to FIG. 5, which shows a circuit diagram of the current source circuit according to the third embodiment of the present invention. As shown in the figure, the element groups outputting the mirror currents I11˜I1n, I21˜I2n, I31˜I3n, I41-I4n may be divided into four current mirror circuits 11, 21, 31, 41. In other words, the embodiment does not limit the element count in each of the current mirror circuits 11, 21, 31, 41. Compared to the embodiment in FIG. 2, the embedment in FIG. 5 further comprises a third current mirror circuit 31, a fourth current mirror circuit 41, a third reference current source NR3, and a fourth reference current source NR4. Thereby, the reference currents further include a third reference current Ir31 and a fourth reference current Ir41. Hence, when dynamic element matching is performed on the first current mirror circuit 11 and the second current mirror circuit 21, the mirror currents I11˜I1n, I21˜I2n are generated according to the reference currents Ir31, Ir41, respectively, generated by the third reference current source NR3 and the fourth reference current source NR4, respectively. Likewise, a plurality of mirror currents I31˜I3n, I41˜I4n are generated according to the reference currents Ir11, Ir21, respectively, generated by the first reference current source NR1 and the second reference current source NR2, respectively. Thereby, by means of the switching of the switching circuit 30, the influence of process variations in the reference current sources NR1˜NR4 on the current source circuit may be lowered. In addition, the numbers of reference current sources according to the embodiments in FIG. 5 and FIG. 3 are different; the element groups are divided into the number of current mirror circuits different from other embodiments. Nonetheless, the technical contents are similar to those described in the above embodiments. The number of the reference current sources and the division for the current mirror circuits will not influence the technical contents.

Please refer again to FIG. 5. According to an embodiment of the present invention, the switching circuit 30 transmits the first reference current Ir11, the second reference current Ir21, the third reference current Ir31, and the fourth reference current Ir41 to the current mirror circuits 11, 21, 31, 41, respectively. In addition, the switching circuit 30 exchangeably transmits the reference currents Ir11, Ir21, Ir31, Ir41 received by adjacent current mirror circuits 11, 21, 31, 41. Thereby, the number of switches, and hence the circuit area, may be reduced. For example, if the switching circuit 11 is switched to the left, the first current mirror circuit 11 generates the first mirror currents I11˜I1n according to the fourth reference current Ir41, instead of according to the first reference current Ir11. Likewise, the second current mirror circuit 21 generates the second mirror currents I21˜I2n according to the first reference current Ir11, instead of according to the second reference current Ir21. The third current mirror circuit 31 generates the third mirror currents I31˜I3n according to the second reference current Ir21, instead of according to the third reference current Ir31. The fourth current mirror circuit 41 generates the fourth mirror currents I41˜I4n according to the third reference current Ir31, instead of according to the fourth reference current Ir41.

Alternatively, if the switching circuit 11 is switched to the right, the first current mirror circuit 11 generates the first mirror currents I11˜I1n according to the second reference current Ir21, instead of according to the first reference current Ir11. Likewise, the second current mirror circuit 21 generates the second mirror currents I21˜I2n according to the third reference current Ir31, instead of according to the second reference current Ir21. The third current mirror circuit 31 generates the third mirror currents I31˜I3n according to the fourth reference current Ir41, instead of according to the third reference current Ir31. The fourth current mirror circuit 41 generates the fourth mirror currents I41˜I4n according to the first reference current Ir11, instead of according to the fourth reference current Ir41. One of switching methods as described above are used for examples, not for limiting the present invention.

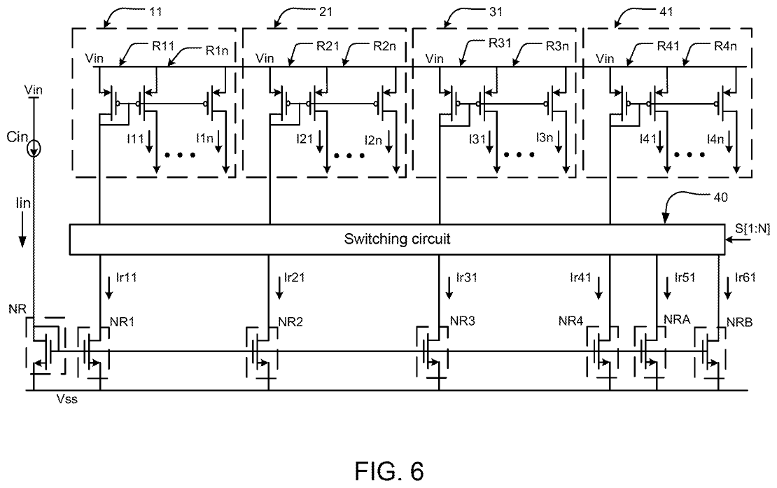

Please refer to FIG. 6, which shows a circuit diagram of the current source circuit according to the fourth embodiment of the present invention. As shown in the figure, compared to the embodiment in FIG. 5, the embodiment in FIG. 6 further comprises another two reference current sources NRA, NRB. The additional fifth and sixth reference current sources NRA, NRB may increase the matching choices in dynamic element matching. Namely, the first to fourth current mirror circuits 11, 21, 31, 41 generate the mirror currents I11˜I1n, I21-I2n, I31˜I3n, I41˜I4n, respectively, according to the reference currents Ir11, Ir21, Ir31, Ir41, Ir51, or Ir61 generated by at least four of the six reference current sources NR1, NR2, NR3, NR4, NRA, NRB, respectively. The method for dynamic element matching according to the embodiment in FIG. 6 can refer to the above description. The details will not be repeated again.

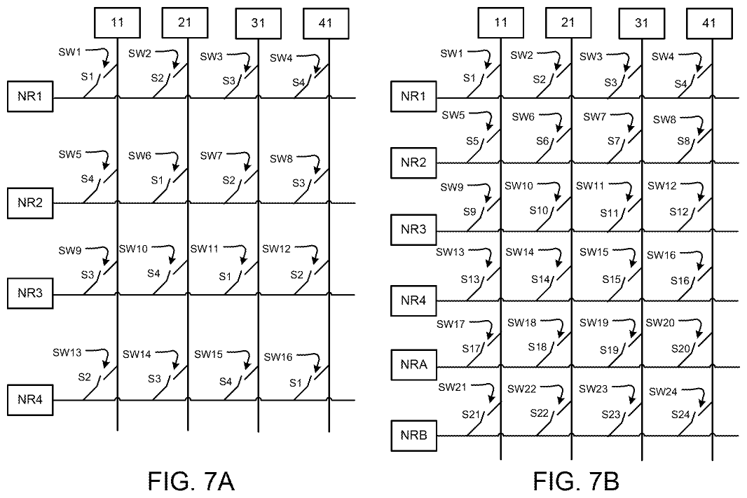

Please refer to FIG. 7A, which shows a circuit diagram of the switching circuit in FIG. 5 according to the present invention. As shown in the figure, the switching circuit 30 according to the embodiment in FIG. 5 includes 16 switches SW1˜SW16. In addition, according to the embodiment in FIG. 7A, each of the switching signals S1˜S4 controls multiple switches SW1˜SW16. For example, the first switching signal S1 controls four switches SW1, SW6, SW11, SW16; the second switching signal S2 controls four switches SW2, SW7, SW12, SW13; the third switching signal S3 controls four switches SW3, SW8, SW9, SW14; and the fourth switching signal S4 controls four switches SW4, SW5, SW10, SW15. Thereby, when the first switching signal S1 controls the switches SW1, SW6, SW11, SW16 to close, the second to fourth switching signals S2-S4 control the rest switches SW2˜SW5, SW7˜SW10, SW12˜SW15 to open, and so on. In other words, according to the embodiment in FIG. 7A, every four switches of the switches SW1-SW16 may be coupled to the same switching signal for reducing the number of switching signals. Thereby, the first and fourth switches SW1, SW4 according to the embodiment in FIG. 4A may be coupled to the same switching signal S1 or S4 for reducing the number of switching signals, instead of different switching signals S1, S4, respectively.

Please refer to FIG. 7B, which shows a circuit diagram of the switching circuit in FIG. 6 according to the present invention. As shown in the figure, the switching circuit 40 in FIG. 6 includes 24 switches SW-SW24. Besides, the embodiment in FIG. 7B is similar to the embodiment in FIG. 4B. Namely, the 24 switches SW1˜SW24 are coupled to 24 different switching signals S1˜S24. The switching method will not be repeated again.

Moreover, the current source circuit according to the present invention may be applied to various circuits requiring currents. For example, it may be applied to the driving circuit of an organic light-emitting diode (OLED) display panel for supplying currents required for driving the OLED. When the current source circuit according to the present invention is applied to a color OLED panel, a plurality of current source circuits may be designed to supply currents corresponding to different colors, respectively. For example, three current source circuits correspond to red, green, and blue OLEDs, respectively, and supply appropriate currents to red, green, and blue OLEDs, respectively. Nonetheless, the applications of the present invention are not limited to the driving circuit for display panels.

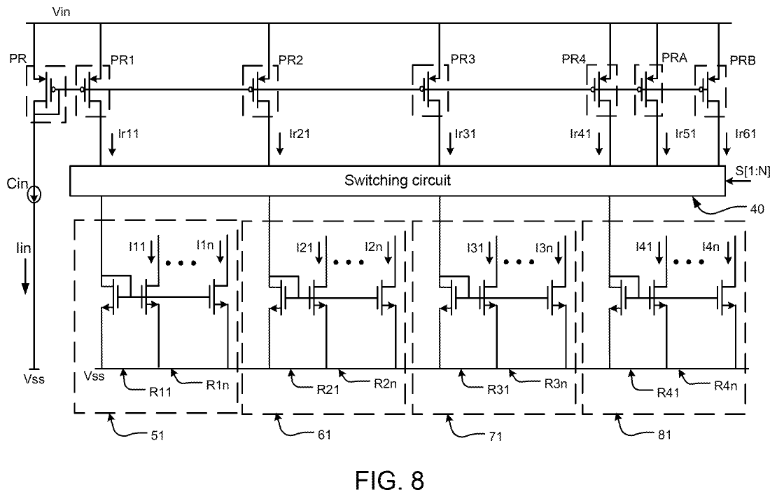

Please refer to FIG. 8, which shows a circuit diagram of the current source circuit according to the fifth embodiment of the present invention. As shown in the figure, the input circuit PR and a plurality of reference current sources PR1, PR2, PR3, PR4, PRA, PRB according to the embodiment in FIG. 8 include PMOS transistors; the element groups of the first to fourth current mirror circuits 51, 61, 71, 81 are NMOS transistors. Nonetheless, according to the embodiments in FIGS. 2, 3, 5, 6, the input circuit NR and a plurality of reference current sources NR1, NR2, NR3, NR4, NRA, NRB according to the embodiment in FIG. 8 include NMOS transistors; the element groups of the first to fourth current mirror circuits 11, 21, 31, 41 are PMOS transistors. The input circuit PR according to the embodiment in FIG. 8 is coupled between the input voltage Vin and the current source Cin. The current source Cin is coupled to the reference level Vss. The current mirror circuit 51, 61, 71, 81 are connected in parallel and coupled between the switching circuit 40 and the reference level Vss. The reference current sources PR1, PR2, PR3, PR4, PRA, PRB are coupled between the switching circuit 40 and the input voltage Vin.

To sum up, the present invention provides a current source circuit, which comprises a current generating circuit, a plurality of current mirror circuits, and a switching circuit. The current generating circuit generates a plurality of reference currents, which include a first reference current and a second reference current. The current mirror circuits output a plurality of mirror currents according to the first reference current and the second reference current. The switching circuit is coupled between the current generating circuit and the current mirror circuits. The first reference current flows to the current mirror circuits via the switching circuit, and the second reference current flows to the current mirror circuits via the switching circuit. Thereby, by using one of the various switching methods controlled by the switching circuit, dynamic element matching may be performed between current mirror circuits and current sources for a specific period, respectively. Consequently, output current (mirror currents) mismatches caused by elements of process variations may be reduced.

1. A current source circuit, comprising:
a current generating circuit, generating a plurality of reference currents, said reference currents including a first reference current and a second reference current;
a plurality of current mirror circuits, outputting a plurality of mirror currents according to said first reference current and said second reference current; and
a switching circuit, coupled between said current generating circuit and said current mirror circuits, said first reference current flowing to said current mirror circuits via said switching circuit, and said second reference current flowing to said current mirror circuits via said switching circuit.

2. The current source circuit of claim 1, wherein said current generating circuit comprises:
a first reference current source, generating said first reference current; and
a second reference current source, generating said second reference current;
wherein said mirror currents include at least one first mirror current and at least one second mirror current; and said current mirror circuits includes:
a first current mirror circuit, coupled to said first reference current source via said switching circuit, generating said first mirror current according to said first reference current, coupled to said second reference current source via said switching circuit, and generating said first mirror current according to said second reference current; and
a second current mirror circuit, coupled to said second reference current source via said switching circuit, generating said second mirror current according to said second reference current, coupled to said first reference current source via said switching circuit, and generating said second mirror current according to said first reference current.

3. The current source circuit of claim 1, comprising:
a current source, coupled to said current generating circuit, and said current generating circuit generating said first reference current and said second reference current according to an input current generated by said current source.

4. The current source circuit of claim 1, wherein said current generating circuit generates a third reference current, said third reference current flows to said current mirror circuits via said switching circuit; and said current mirror circuits generate said mirror currents according to at least two reference currents of said first reference current to said third reference current.

5. The current source circuit of claim 1, wherein the number of said reference currents is greater than the number of said current mirror circuits.

6. The current source circuit of claim 1, wherein said current mirror circuits are coupled between an input voltage and said switching circuit; and said current generating circuit is coupled to a current source and between said switching circuit and a reference level.

7. The current source circuit of claim 1, wherein said current mirror circuits are coupled between said switching circuit and a reference level; and said current generating circuit is coupled to a current source and between said switching circuit and an input voltage.

8. The current source circuit of claim 1, wherein said switching circuit includes:
a first switch, coupled between a first current mirror circuit of said current mirror circuits and said first reference current of said current generating circuit;
a second switch, coupled between a second current mirror circuit of said current mirror circuits and said first reference current;
a third switch, coupled between said first current mirror circuit and said second reference current of said current generating circuit; and
a fourth switch, coupled between said second current mirror circuit and said second reference current;
wherein said first reference current flows to said first current mirror circuit via said first switch and said second reference current flows to said second current mirror circuit via said fourth switch; alternatively, said first reference current flows to said second current mirror circuit via said second switch and said second reference current flows to said first current mirror circuit via said third switch.

9. The current source circuit of claim 1, wherein said switching circuit includes:
a first switch, coupled between a first current mirror circuit of said current mirror circuits and said first reference current of said current generating circuit;
a second switch, coupled between a second current mirror circuit of said current mirror circuits and said first reference current;
a third switch, coupled between said first current mirror circuit and said second reference current of said current generating circuit;
a fourth switch, coupled between said second current mirror circuit and said second reference current;
a fifth switch, coupled between a third reference current of said current generating circuit and said first current mirror circuit; and
a sixth switch, coupled between said third reference current and said second current mirror circuit;
wherein said first reference current flows to said first current mirror circuit via said first switch and said second reference current flows to said second current mirror circuit via said fourth switch; alternatively, said first reference current flows to said second current mirror circuit via said second switch and said second reference current flows to said first current mirror circuit via said third switch; alternatively, said third reference current flows to said first current mirror circuit via said fifth switch and said first reference current flows to said second current mirror circuit via said second switch; alternatively, said third reference current flows to said first current mirror circuit via said fifth switch and said second reference current flows to said second current mirror circuit via said fourth switch; alternatively, said first reference current flows to said first current mirror circuit via said first switch and said third reference current flows to said second current mirror circuit via said sixth switch; alternatively, said second reference current flows to said first current mirror circuit via said third switch and said third reference current flows to said second current mirror circuit via said sixth switch.

10. The current source circuit of claim 1, wherein said reference currents further include a third reference current and a fourth reference current; said switching circuit transmits said first reference current, said second reference current, said third reference current, and said fourth reference current to said current mirror circuits, respectively; and said switching circuit exchangeably transmits said reference currents received by adjacent current mirror circuits.
